(19) United States
(12) Patent Application Publication
(10) Pub. No.: US 2026/0182261 A1
(43) Pub. Date: Jun. 25, 2026

(54) RRAM AND FABRICATING METHOD OF THE SAME

(71) Applicant: UNITED MICROELECTRONICS CORP., Hsin-Chu City (TW)

(72) Inventors: Wen-Jen Wang, Tainan City (TW); Yu-Huan Yeh, Taichung City (TW); Chuan-Fu Wang, Miaoli County (TW)

(73) Assignee: UNITED MICROELECTRONICS CORP., Hsin-Chu City (TW)

(21) Appl. No.: 19/452,423

(22) Filed: Jan. 19, 2026

Related U.S. Application Data
(63) Continuation of application No. 18/224,054, filed on Jul. 19, 2023, now Pat. No. 12,557,562.

(30) Foreign Application Priority Data
Jun. 21, 2023 (CN) 202310742341.5

(51) Int. Cl. H10N 70/00; H10B 63/00; H10N 70/20

(52) U.S. Cl. CPC H10N 70/8265; H10B 63/80; H10N 70/011; H10N 70/24; H10N 70/8833

(57) ABSTRACT

An RRAM string includes a substrate and numerous RRAM cells disposed on the substrate in a memory region. The RRAM cells include at least two last RRAM cells and one middle RRAM cell. Each RRAM cell includes a bottom electrode, a resistive switching layer, a top electrode, and a cap layer stacked from bottom to top. A first spacer contacts a first sidewall of the bottom electrode and a second sidewall of the resistive switching layer. A second spacer contacts the first spacer and a third sidewall of the top electrode. Furthermore, a dielectric layer covers the second spacer in the memory region. The dielectric layer at an outer side of the last RRAM cells includes a slope. An end of the slope contacts the second spacer located on a surface of the substrate.

### CROSS REFERENCE TO RELATED APPLICATIONS

This application is a continuation application of U.S. application Ser. No. 18/224,054, filed on Jul. 19, 2023. The content of the application is incorporated herein by reference.

### BACKGROUND OF THE INVENTION

### 1. Field of the Invention

The invention relates to a resistive random access memory (RRAM) cell with two stacked spacers and a manufacturing method thereof, and particularly to a manufacturing method of an RRAM cell with two stacked spacers to block oxygen atoms.

### 2. Description of the Prior Art

Nonvolatile memory is capable of retaining the stored information even when unpowered. Non-volatile memory may be used for secondary storage or long-term persistent storage. RRAM technology has been gradually recognized as having exhibited those semiconductor memory advantages.

RRAM cells are non-volatile memory cells that store information by changes in electric resistance, not by changes in charge capacity. In general, the resistance of the resistive layer varies according to an applied voltage. An RRAM cell can be in a plurality of states in which the electric resistances are different. Each different state may represent digital information. The state can be changed by applying a predetermined voltage or current between the electrodes. A state is maintained as long as a predetermined operation is not performed.

With the growth of electronic data, the demand of higher memory capacity, longer lifespan and faster read and write speed of RRAM has increased significantly. In order to achieve high performance operation, it is necessary to increase the retention and endurance of RRAM.

### SUMMARY OF THE INVENTION

In light of the above, the present invention provides an RRAM cell with two stacked spacers to increase the reliability of the RRAM cell.

According to a preferred embodiment of the present invention, an RRAM string includes a substrate and numerous RRAM cells disposed on the substrate in a memory region.

The RRAM cells include two last RRAM cells and one middle RRAM cell. Each of the RRAM cells includes a bottom electrode, a resistive switching layer, a top electrode, and a cap layer stacked from bottom to top. A first spacer contacts a first sidewall of the bottom electrode and a second sidewall of the resistive switching layer. A second spacer contacts the first spacer and a third sidewall of the top electrode. Furthermore, a dielectric layer covers the second spacer in the memory region. The dielectric layer at an outer side of the last RRAM cells includes a slope. An end of the slope contacts the second spacer located on a surface of the substrate.

According to another preferred embodiment of the present invention, a fabricating method of an RRAM string includes forming numerous RRAM cells stacking on a memory region of a substrate. Each RRAM cell respectively includes a bottom electrode, a resistive switching layer, a top electrode, and a cap layer. Later, a first spacer is formed to contact a first sidewall of the bottom electrode and a second sidewall of the resistive switching layer. Next, a second spacer material layer is formed to cover the first spacer and the RRAM cells. Subsequently, a dielectric layer is formed to cover the second spacer material layer. After that, an etching back process is performed without a mask to remove the dielectric layer and the second spacer material layer from a top surface of the cap layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabricating method of an RRAM cell according to a preferred embodiment of the present invention; wherein:

FIG. 1 depicts a substrate including a memory region and a logic device region thereon;

FIG. 2 is a fabricating stage in continuous from FIG. 1;

FIG. 3 is a fabricating stage in continuous from FIG. 2;

FIG. 4 is a fabricating stage in continuous from FIG. 3;

FIG. 5 is a fabricating stage in continuous from FIG. 4; and

FIG. 6 is a fabricating stage in continuous from FIG. 5.

FIG. 7 depicts an RRAM string according to a preferred embodiment of the present invention.

FIG. 8 depicts a fabricating method for a metal line on an RRAM cell according to a preferred embodiment of the present invention.

### DETAILED DESCRIPTION

FIG. 1 to FIG. 6 depict a fabricating method of an RRAM cell according to a preferred embodiment of the present invention.

As shown in FIG. 1, a substrate 10 is provided. The substrate 10 includes a memory region M and a logic device region L. A conductive line 12 is embedded within the memory region M of the substrate 10. Then, a bottom electrode material layer, a resistive switching material layer, a top electrode material layer and a cap material layer are formed from bottom to top to cover the memory region M and the logic device region L.

Later, the bottom electrode material layer, the resistive switching material layer, the top electrode material layer and the cap material layer are patterned to form a bottom electrode 14, a resistive switching layer 16, a top electrode 18 and a cap layer 20 staked from bottom to top in the memory region M and the bottom electrode material layer, the resistive switching material layer, the top electrode material layer and the cap material layer within the logic device region L are completely removed. The cap layer 20 includes a top surface 20a and two fourth sidewalls 20b, and an edge of the top surface 20a connects to each of the two fourth sidewalls 20b. The bottom electrode 14 directly contacts the conductive line 12. The conductive line 12 may include copper, aluminum, tungsten or other conductive materials.

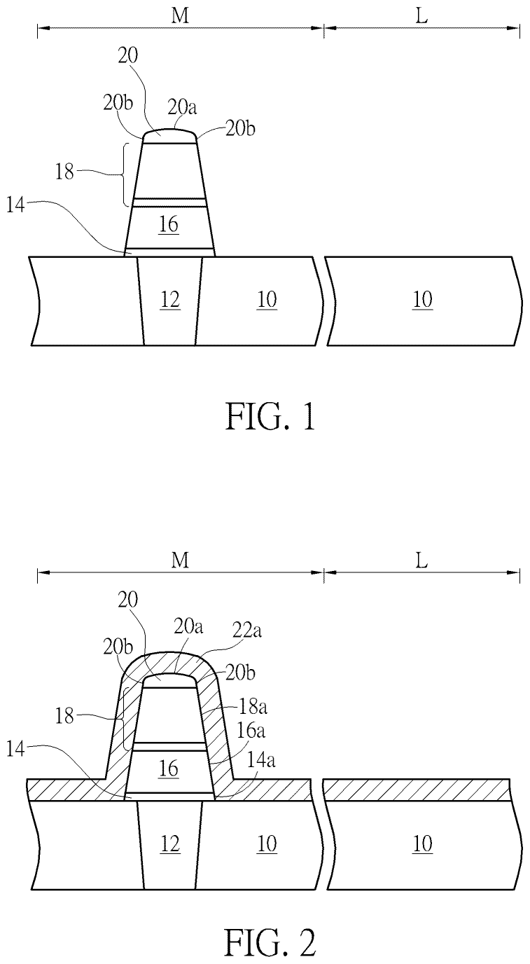

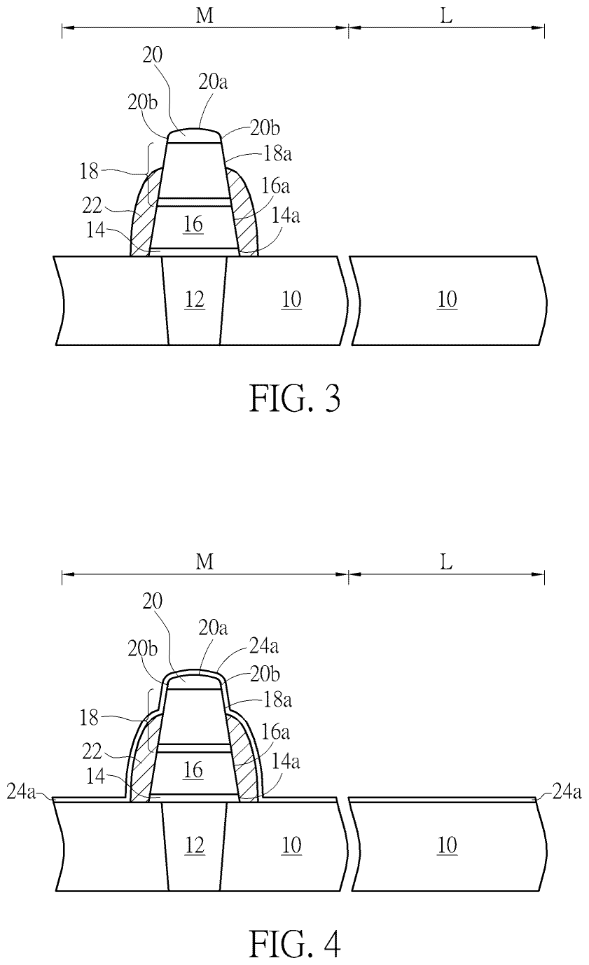

As shown in FIG. 2 and FIG. 3, a first spacer material layer 22a is formed to conformally cover the bottom electrode 14, the resistive switching layer 16, the top electrode 18, the cap layer 20, the substrate 10 of the memory region M and the substrate 10 of the logic device region L. Later, the first spacer material layer 22a is etched to remove the first spacer material layer 22a on the top surface 20a of the cap layer 20, on the fourth sidewalls 20b and on part of the third sidewall 18a of the top electrode 18 to form a first spacer 22 respectively at two sides of the bottom electrode 14, the resistive switching layer 16 and the top electrode 18. When forming the first spacer 22, the first spacer material layer 22a within the logic device region L is also removed. The first spacer 22 is preferably silicon nitride. The first spacer 22 preferably directly contacts part of the third sidewall 18a of the top electrode 18, an entirety of the first sidewall 14a of the bottom electrode 14 and an entirety of the second sidewall 16a of the resistive switching layer 16. Furthermore, the first spacer 22 does not contact the fourth sidewalls 20b and the top surface 20a of the cap layer 20.

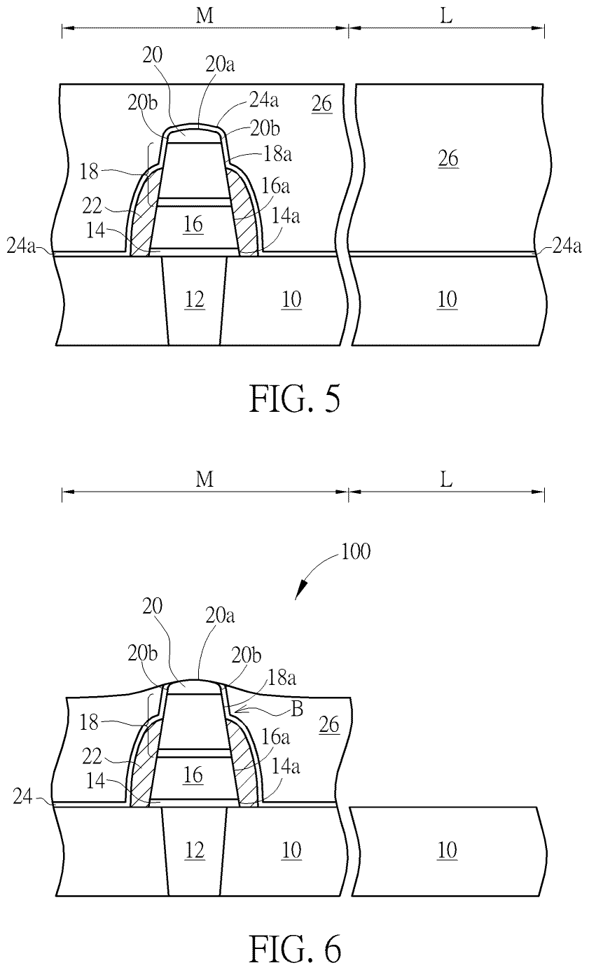

As shown in FIG. 4, a second spacer material layer 24a is formed to conformally cover the first spacer 22, contact the top electrode 18, contact the cap layer 20, and contact the substrate 10 within the memory region M and the substrate 10 within the logic device region L. The second spacer material layer 24a directly contacts the first spacer 22. As shown in FIG. 5, a dielectric layer 26 is formed to cover the second spacer material layer 24a, the substrate 10 within the memory region M and the substrate 10 within the logic device region L, wherein the dielectric layer 26 contacts the second spacer material layer 24a. The dielectric layer 26 preferably includes silicon oxide. As shown in FIG. 6, the dielectric layer 26 and the second spacer material layer 24a are etched back to completely remove the second spacer material layer 24a and the dielectric layer 26 on the top surface 20a and completely remove the second spacer material layer 24a and the dielectric layer 26 within the logic device region L. After the second spacer material layer 24a on the top surface 20a is removed, the second spacer material layer 24a is segmented into numerous individual second spacers 24. The second spacer material layer 24a form a second spacer 24 respectively located on two sides of the lower electrode 14, the resistive switching layer 16, and the top electrode 18, and the cap layer 20. The second spacer 24 is preferably silicon nitride, and the second spacer 24 needs to cover the third sidewall 18a not covered by the first spacer 22 to protect the top electrode 18 from being damaged in the subsequent process. The second spacer 24 on the first spacer 22 extends to contact the substrate 10 in the memory region M.

Now, an RRAM cell 100 of the present invention is completed. When etching back the dielectric layer 26 and the second spacer material layer 24a, no mask is used. By using loading effect, the dielectric layer 26 and the second spacer material layer 24a in the logic device region L are removed and the second spacer material layer 24a in the memory region M is segmented The loading effect refers to the difference in the density of device in the logic device region L and the memory region M causes different etching rate.

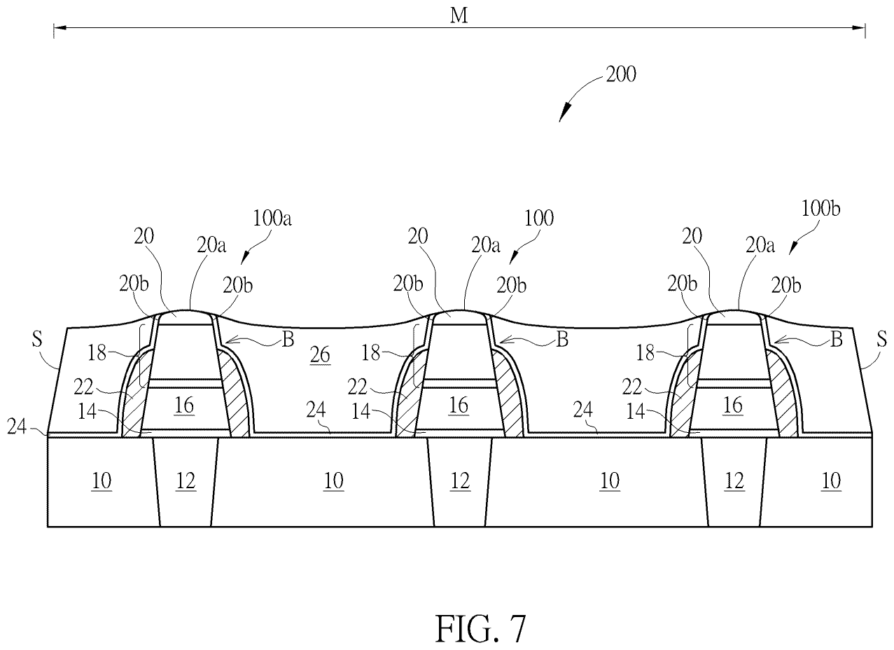

FIG. 7 depicts an RRAM string according to another preferred embodiment of the present invention.

Please refer to FIG. 6 and FIG. 7. The RRAM cell 100 shown in FIG. 6 is located in the middle of the RRAM string 200. In details, there is an RRAM cell 100a at the left side of the RRAM 100 cell and an RRAM cell 100b at the right side of the RRAM cell 100. The RRAM string 200 is located in the memory area M. The structures of RRAM cell 100, the RRAM cell 100a and the RRAM cell 100b are the same.

The second spacer 24 on one side of the RRAM cell 100a extends to the substrate 10 and the second spacer 24 on one side of the RRAM cell 100 also extends to the substrate 10. The second spacer 24 on the RRAM cell 100a and the second spacer 24 on the RRAM cell 100 are connected on the substrate 10. Furthermore, in the RRAM string 200, the RRAM cell 100a and the RRAM cell 100b are respectively the last RRAMs in the RRAM string 200.

After the step of etching back the dielectric layer 26 and the second spacer material layer 24a as shown in FIG. 6, since the RRAM cell 100a and the RRAM cell 100b are at the last of the RRAM string 200, the dielectric layer 26 on one side of the RRAM cell 100a and on one side of the RRAM cell 100b has a slope S because of the loading effect. The end of the slope S contacts the second spacer 24 located on the surface of the substrate 10. However, because the RRAM cell 100 is at the middle of the RRAM string 200, the surface of the dielectric layer 26 on both sides of the RRAM cell 100 is substantially flat.

As shown in FIG. 6, according to a preferred embodiment of the present invention, an RRAM cell 100 includes a bottom electrode 14, a resistive switching layer 16, a top electrode 18 and a cap layer 20 stacked from bottom to top. A first spacer 22 contacts a first sidewall 14a of the bottom electrode 14, and a second sidewall 16a of the resistive switching layer 16. A second spacer 24 contacts the first spacer 22 and contacts a third sidewall 18a of the top electrode 18. The third sidewall 18a aligns with the fourth sidewalls 20a. A thickness of the first spacer 22 is greater than a thickness of the second spacer 24. The cap layer 20 includes a top surface 20a and two fourth sidewalls 20b, and an edge of the top surface 20a connects to each of the two fourth sidewalls 20b. According to a preferred embodiment of the present invention, a thickness of the first spacer 22 is between 250 angstroms and 500 angstroms, and a thickness of the second spacer 24 is between 100 angstroms and 150 angstroms. A total thickness of the first spacer 22 and the spacer 24 is between 350 angstroms and 650 angstroms. It is noteworthy that the first spacer 22 and the second spacer 24 do not cover the top surface 20a of the cap layer 20, and the first spacer 22 does not contact the fourth sidewalls 20b.

In addition, the first spacer 22 preferably extends from the second sidewall 16a to contact part of the third sidewall 18a. That is, the first spacer 22 must at least cover the second sidewall 16a of the resistive switching layer 16 completely. The second spacer 24 extends from surface of the first spacer 22 to the surface of the substrate 10. A dielectric layer 26 covers the second spacer 24 and the memory region M. The top surface 20a is exposed through the dielectric layer 26. Moreover, the dielectric layer 26, the second spacer 24, the first spacer 22, the bottom electrode 14, the resistive switching layer 16, the top electrode 18 and the cap layer 20 are not in the logic device region L.

Furthermore, an entirety of a thickness of the second spacer 24 is the same. In addition, a cross-section of the first spacer 22 includes a sail-shaped profile. The second spacer 24 contacts the third sidewall 18a and the second spacer 24 contacts a top surface of the first spacer 22 together form a bend B, and the bend B is concave toward the top electrode 18.

The substrate 10 includes a silicon substrate, a germanium substrate, a gallium arsenide substrate, a silicon germanium substrate, an indium phosphide substrate, a gallium nitride substrate, a silicon carbide substrate or a silicon-on-insulator substrate. The resistive switching layer 16 includes tantalum oxide, nickel oxide, hafnium oxide, titanium oxide or other transition metal oxides. The top electrode 18 and the bottom electrode 14 may respectively include tantalum, titanium, iridium, titanium nitride, tantalum nitride and other conductive materials. The cap layer 20 is preferably silicon oxide.

The first spacer 22 and the second spacer 24 are preferably silicon nitride. The dielectric layer 26 is silicon oxide. Since the ambient temperature during the operation of the RRAM cell 100 is greater than 120° C., if only the second spacer 24 is used and the first spacer 22 is not provided, when the temperature is above 120° C., oxygen atoms from the dielectric layer 26 will penetrate the second spacer 24 and enter the resistive switching layer 16, and the resistance of the RRAM cell 100 at the low resistance state will decrease. Therefore, in the present invention, the first spacer 22 with a larger thickness is specially added to work with the second spacer 24 to block oxygen atoms.

In addition, by using a single layer of the second spacer 24, but increasing the thickness of the second spacer 24a can also block oxygen atoms, however, problems will occur in the etching back step illustrated in FIG. 6. In details, because current etching back is only suitable for removing thin material layers such as silicon nitride smaller than 200 angstroms. If the thickness of the second spacer 24 is thickened to become more than 200 angstroms to block oxygen atoms, during the etching back, there will be second spacer material layers 24a remained in the logic device region L.

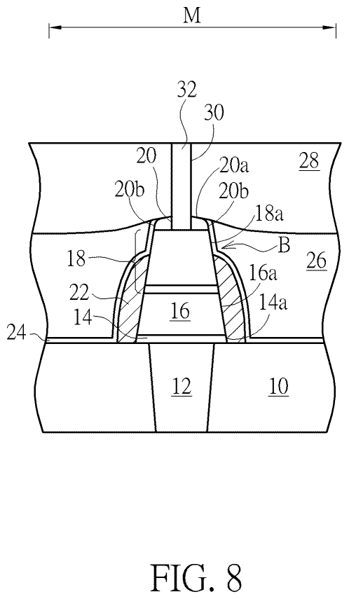

In addition, as shown in FIG. 8, after the RRAM cell 100 is completed, a metal interconnection process can be performed. For example, a dielectric layer 28 is formed to cover the dielectric layer 26. The dielectric layer 28 is preferably silicon oxide. Later, the dielectric layer 28 and cap layer 20 are etched to form a trench 30 within the dielectric layer 28 and the cap layer 20. Finally, metal is filled in the trench 30 to form a metal line 32. Because the second spacer material layer 24a on the top surface 20a of the cap layer 20 is removed in the etching back of FIG. 6, when forming the trench 30, only the dielectric layer 28 and the cap layer 20 need to be etched. If the second spacer material layer 24a on the top surface 20a of the cap layer 20 is not removed, an extra layer which is the second spacer material layer 24a has to be etched while forming the trench 30. However, the second spacer material layer 24a is silicon nitride. Because the etching conditions for forming the trench 30 are more suitable for etching silicon oxide, the second spacer material layer 24a will be etched incompletely. In the present invention, the problem of incomplete formation of the trench 30 is avoided by removing the second spacer material layer 24a on the top surface 20a in advance.

As shown in FIG. 6 and FIG. 7, in accordance with an embodiment of the present invention, an RRAM string 200 is provided. The RRAM string 200 includes a substrate 10 and numerous RRAM cells 100/100a/100b disposed on the substrate 10 in a memory region M. The RRAM cells 100a/100b are disposed at last of the RRAM string 200. The RRAM cells 100a/100b can be called as last RRAM cells 100a/100b. The RRAM cell 100 is disposed at the middle of the RRAM string 200. The RRAM cell 100 can be called as a middle RRAM cell 100. Each RRAM cell 100/100a/100b includes a bottom electrode 14, a resistive switching layer 16, a top electrode 18, and a cap layer 20 stacked from bottom to top. A first spacer 22 contacts a first sidewall 14a of the bottom electrode 14 and a second sidewall 16a of the resistive switching layer 16. A second spacer 24 contacts the first spacer 22 and further contacts a third sidewall 18a of the top electrode 18. Furthermore, a dielectric layer 26 covers the second spacer 24 in the memory region M. The dielectric layer 26 at an outer side of the last RRAM cells 100a/100b includes a slope S. An end of the slope S contacts the second spacer 24 located on a surface of the substrate 10.

As shown in FIG. 7, in accordance with another embodiment of the present invention, a fabricating method of an RRAM string 200 includes forming numerous RRAM cells 100/100a/100b stacking on a memory region M of a substrate 10. Each RRAM cell 100/100a/100b respectively includes a bottom electrode 14, a resistive switching layer 16, a top electrode 18, and a cap layer 20. Later, a first spacer 22 is formed to contact a first sidewall 14a of the bottom electrode 14 and a second sidewall 16a of the resistive switching layer 16. Next, a second spacer material layer 24a is formed to cover the first spacer 22 and the RRAM cells. Please refer to FIG. 4 for the position of the second spacer material layer 24a. Subsequently, a dielectric layer 26 is formed to cover the second spacer material layer 24a. After that, an etching back process is performed without a mask to remove the dielectric layer 26 and the second spacer material layer 24a from a top surface 20a of the cap layer 20.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A resistive random access memory (RRAM) string, comprising:
a substrate;
a plurality of RRAM cells disposed on the substrate in a memory region, the plurality of RRAM cells comprising at least two last RRAM cells and at least one middle RRAM cell located between the last RRAM cells, each RRAM cell comprising a bottom electrode, a resistive switching layer, a top electrode, and a cap layer stacked from bottom to top;
a first spacer contacting a first sidewall of the bottom electrode and a second sidewall of the resistive switching layer;
a second spacer contacting the first spacer and contacting a third sidewall of the top electrode; and
a dielectric layer covering the second spacer in the memory region;
wherein, the dielectric layer at an outer side of the last RRAM cells comprises a slope, and an end of the slope contacts the second spacer located on a surface of the substrate.

2. The RRAM string of claim 1, wherein a surface of the dielectric layer on both sides of the middle RRAM cell is substantially flat.

3. The RRAM string of claim 1, wherein the second spacer on the last RRAM cell and the second spacer on the middle RRAM cell are connected on the substrate.

4. The RRAM string of claim 1, wherein the third sidewall of the top electrode comprises a lower portion and an upper portion, and the first spacer further contacts the lower portion of the third sidewall.

5. The RRAM string of claim 4, wherein the second spacer covers the upper portion of the third sidewall not covered by the first spacer.

6. The RRAM string of claim 1, wherein the first spacer and the second spacer do not cover a top surface of the cap layer.

7. The RRAM string of claim 1, wherein a thickness of the first spacer is greater than a thickness of the second spacer.

8. The RRAM string of claim 1, wherein the second spacer contacting the third sidewall and the second spacer contacting a top surface of the first spacer together form a bend, and the bend is concave toward the top electrode.

9. The RRAM string of claim 1, wherein a cross-section of the first spacer comprises a sail-shaped profile.

10. The RRAM string of claim 1, wherein the first spacer and the second spacer comprise silicon nitride, and the dielectric layer and the cap layer comprise silicon oxide.

11. The RRAM string of claim 1, wherein the cap layer comprises two fourth sidewalls, and the third sidewall of the top electrode aligns with the fourth sidewalls.

12. The RRAM string of claim 1, further comprising a conductive line embedded within the substrate, wherein the bottom electrode directly contacts the conductive line.

13. The RRAM string of claim 1, further comprising an additional dielectric layer covering the dielectric layer, and a trench disposed within the additional dielectric layer and the cap layer.

14. The RRAM string of claim 13, further comprising a metal line filled in the trench.

15. A fabricating method of a resistive random access memory (RRAM) string, comprising:
forming a plurality of RRAM cells on a memory region of a substrate, each RRAM cell comprising a bottom electrode, a resistive switching layer, a top electrode, and a cap layer;
forming a first spacer contacting a first sidewall of the bottom electrode and a second sidewall of the resistive switching layer;
forming a second spacer material layer covering the first spacer and the plurality of RRAM cells;
forming a dielectric layer covering the second spacer material layer; and
performing an etching back process without a mask to remove the dielectric layer and the second spacer material layer from a top surface of the cap layer.

16. The fabricating method of an RRAM string of claim 15, wherein the etching back process utilizes a loading effect to segment the second spacer material layer into a plurality of individual second spacers in the memory region.

17. The fabricating method of an RRAM string of claim 16, wherein after performing the etching back process, the dielectric layer forms a slope at an outer side of the RRAM string, wherein an end of the slope contacts one of the plurality of individual second spacers on the substrate.

18. The fabricating method of an RRAM string of claim 15, wherein the substrate further comprises a logic device region, and the dielectric layer forms on the logic device region, and the etching back process completely removes the dielectric layer from the logic device region.

19. The fabricating method of an RRAM string of claim 15, further comprising forming a trench through the cap layer before forming a metal line, after the etching back process.
